(19) United States
(12) Patent Application Publication
(10) Pub. No.: US 2025/0136441 A1
(43) Pub. Date: May 1, 2025

(54) WAFER-LEVEL FABRICATION PROCESSES FOR FERRIMAGNETIC RESONATORS AND RESONATOR DEVICES

(71) Applicant: THE REGENTS OF THE UNIVERSITY OF CALIFORNIA, Oakland, CA (US)

(72) Inventors: Andrei M. SHKEL, Irvine, CA (US); Danmeng WANG, Irvine, CA (US); Austin R. PARRISH, Irvine, CA (US)

(73) Assignee: THE REGENTS OF THE UNIVERSITY OF CALIFORNIA, Oakland, CA (US)

(21) Appl. No.: 18/730,588

(22) PCT Filed: Jan. 19, 2023
(86) PCT No.: PCT/US2023/060881

§ 371 Date: Jul. 19, 2024

Related U.S. Application Data
(60) Provisional application No. 63/300,886, filed on Jan. 19, 2022.

(51) Int. Cl. B81C 1/00

(52) U.S. Cl. CPC B81C 1/00626; B81B 2201/0271; B81C 2203/0118; B81C 2203/031; B81C 2203/036; B81C 2203/051

(57) ABSTRACT

Systems, processes and devices are provided for wafer-level fabrication of a resonator. A process is provided that includes chemical etching of glass and silicon, high-temperature glassblowing, controlling assembly of at least one YIG sphere relative to a nest structure, and plasma assisted wafer bonding. The process can include formation of loop coils and spherical coils defined by the glassblowing process including inner and outer hemispherical structures. The inner hemispherical structure may provide loops to drive and detect resonance in YIG spheres. Processes discussed herein allow for placement of loops in close proximity (e.g., few microns) to ferrimagnetic elements. The outer hemisphere may provide harmonic magnetic coils for frequency tuning. Embodiments are also directed to a resonator including first and second wafer-level glass blown wafer stacks each with inner hemisphere and outer hemispheres. The resonator includes coupling loop coils, tuning coils, and a sphere element nested between glass blown wafer stacks.

### CROSS REFERENCE TO RELATED APPLICATION

This application is the National Stage entry under 35 U.S.C. § 371 of International Application No. PCT/US2023/060881, titled WAFER-LEVEL FABRICATION PROCESSES FOR FERRIMAGNETIC RESONATORS AND RESONATOR DEVICES filed Jan. 19, 2023, the content of which is expressly incorporated by reference in its entirety.

### FIELD

The present disclosure generally relates to processes, systems and device configurations for fabricating ferrimagnetic resonators, and in particular wafer-level fabrication of resonators, and resonator structures.

### BACKGROUND

Resonators are used for many components and can be constructed to satisfy different frequency requirements. Existing technologies include coaxial, dielectric, crystal, ceramic, surface acoustic wave (SAW), and Yttrium Iron Garnet (YIG). Coaxial resonators can be used to satisfy frequency requirements from 200 MHz to 10 GHz and their sizes range from 2 to 18 mm. Dielectric resonators can cover 250 MHz to 50 GHz and may be implemented with different materials. Conventional resonators may have a fundamental limit in size around 1 mm for the 50 GHz resonators. Quartz crystal resonators, and other electromechanical resonators, have the practical range from 10 KHz to 250 MHz. A surface acoustic wave (SAW) resonator, for example, is generally limited to the range of frequencies from 100 MHz to 1-2 GHZ.

There is a need for improved resonator structures and manufacturing processes. There is also a desire for improvements to YIG oscillators and YIG resonator manufacturing. One disadvantage of existing YIG resonators is the requirement of a “boutique” manufacturing process, resulting in bulky and expensive components. By way of example, conventional fabrication requires a skilled operator to position small components with great precision. For example, U.S. Pat. No. 6,255,918B1 to Parrot et. al. describes a process of fabricating by bending loops into the desired spherical shapes using a beryllium-copper alloy sheet, and electro-welding or a suitable bonding method to attach the spheres to the mounting structure. Existing methods for manufacturing YIG resonators may require specialized tools limiting manufacturing to a single resonator at a time. For example, existing methods can include use of a thermally conducting rod for alignment of elements. Other methods have been presented that enable alignment without an attached rod, however these methods still operate on only one YIG sphere at a time (R. Blight, J. Martin, and E. Schloemann, “Planar YIG Filters,” IEEE Trans. Magn., vol. M, no. 5, pp. 1219-1221, 1984.). US Patent Publication Number US 2011/0148532 A1 to Parrot et. al. describes picking up and placement of single elements for manufacturing. There exists a need for new processes, systems and devices for fabrication of resonators and YIG devices.

### BRIEF SUMMARY OF THE EMBODIMENTS

One or more embodiments are directed to systems and device configurations for fabrication of resonators including wafer-level fabrication of resonators. According to one embodiment, a method includes controlling, by a device, isotropic cavity etching of at least one glass wafer, including a cap wafer and an inner wafer, and controlling, by the device, metallization of the cap wafer and inner wafer, wherein at least one of a top coil and bottom coil are formed. The method also includes controlling, by the device, wafer bonding of the at least one glass wafer with a silicon wafer to form a bonded wafer, and controlling, by the device, glass blowing of the bonded wafer to form a dual hemisphere structure. The method also includes controlling, by the device, removal of a handle wafer from the bonded wafer and controlling, by the device, etching of the bonded wafer to form at least one nest for a sphere element. The method also includes controlling, by the device, assembly of a sphere element with the bonded wafer, and controlling, by the device, wafer-to-wafer bonding of the bonded wafer to form a resonator.

In one embodiment, isotropic cavity etching includes wet etching at least one cavity in the cap wafer and at least one hole for a coil trace and at least on electrode pad in the inner wafer.

In one embodiment, controlling, by the device, etching of the bonded wafer forms at least one nest for a sphere element.

In one embodiment, controlling metallization of the at least one glass wafer includes metallization and patterning of a metal stack on the cap wafer and the inner wafer.

In one embodiment, wafer bonding of the at least one glass wafer with a silicon wafer includes plasma-assisted glass-to-glass bonding of the cap wafer and the inner wafer to form a glass stack, aligning of the glass stack, and bonding of the glass stack to a handle wafer.

In one embodiment, controlling glass blowing includes wafer-scale metal-on-glass stack glassblowing.

In one embodiment, controlling removal of a handle wafer of the bonded wafer includes etching of a silicon substrate layer and wet etching of an oxide layer on the handle wafer.

In one embodiment, controlling etching of the bonded wafer to form at least one nest includes laser micromachining of a silicon device layer.

In one embodiment, controlling assembly includes control of yttrium iron garnet (YIG) spheres with the bonded wafer and includes self-assembly of at least one YIG sphere using surface treatment and mechanical vibration.

In one embodiment, controlling wafer-to-wafer bonding to form a resonator includes encapsulating an yttrium iron garnet (YIG) sphere by plasma assisted silicon-to-silicon wafer-level bonding.

In one embodiment, the method includes controlling, by the device, wafer-level dicing to expose at least one inner electrode pad of a detection coil.

Another embodiment is directed to a system for wafer-level fabrication of a resonator. The system includes a controller, etching unit, metallization unit, glass blowing unit, bonding unit, and YIG assembly unit. The controller is configured to control isotropic cavity etching of at least one glass wafer, including a cap wafer and an inner wafer, and control metallization of the cap wafer and inner wafer, wherein at least one of a top coil and bottom coil are formed. The controller is configured to control wafer bonding of the at least one glass wafer with a silicon wafer to form a bonded wafer, and control glass blowing of the bonded wafer to form a dual hemisphere structure. The controller is configured to control removal of a handle wafer from the bonded wafer, and control etching of the bonded wafer to form at least one nest for a sphere element. The controller is configured to control assembly of a sphere element with the bonded wafer, and control wafer-to-wafer bonding of the bonded wafer to form a resonator.

Another embodiment is directed to a resonator and resonator structure. According to embodiments, a resonator includes a first wafer-level glass blown wafer stack including an inner hemisphere and an outer hemisphere, and a second wafer-level glass blown wafer stack including an inner hemisphere and an outer hemisphere, wherein each wafer-level glass blown wafer stack includes a coupling loop coil on an inner hemisphere and a tuning coil on an outer hemisphere. The resonator also includes a sphere element nested between the first wafer-level glass blown wafer stack and the first wafer-level glass blown wafer stack.

Other aspects. features, and techniques will be apparent to one skilled in the relevant art in view of the following detailed description of the embodiments.

### BRIEF DESCRIPTION OF THE DRAWINGS

The features, objects, and advantages of the present disclosure will become more apparent from the detailed description set forth below when taken in conjunction with the drawings in which like reference characters identify correspondingly throughout and wherein:

FIG. 1 illustrates a process for fabrication of at least one resonator according to one or more embodiments;

FIG. 2 illustrates a graphical representation of a YIG resonator according to one or more embodiments;

FIG. 3 illustrates a process for fabrication of at least one resonator according to one or more embodiments;

FIG. 4 illustrates a graphical representation of YIG resonator according to one or more embodiments;

FIG. 5 illustrates a graphical representation of a YIG resonator elements according to one or more embodiments;

FIGS. 6A-6C graphically illustrate a process for fabrication of a resonator according to one or more embodiments;

FIGS. 7A-7BC illustrate alignment according to one or more embodiments;

FIG. 8 illustrates a tuning coil according to one or more embodiments;

FIG. 9A illustrates a double cavity structure according to one or more embodiments;

FIG. 9B illustrates a bonded wafer stack according to one or more embodiments;

FIG. 9C illustrates a dual hemisphere shell according to one or more embodiments; and

FIG. 10 illustrates a system for fabrication of a resonator according to one or more embodiments.

### DETAILED DESCRIPTION OF THE EXEMPLARY EMBODIMENTS

### Overview and Terminology

Aspects of this disclosure are directed to processes for fabrication of ferrimagnetic resonators including wafer-level fabrication processes of at least one resonator device. In one embodiment, a wafer-level fabrication process includes chemical etching of glass and silicon, high temperature glassblowing processes, self-assembly of YIG spheres, and plasma-assisted wafer bonding. According to embodiments, processes described herein preserve exceptional qualities of a YIG crystal as ferrimagnetic resonator and provide operations to allow for wafer-scale implementation.

According to embodiments, a process is provided that includes preservation of Yttrium Iron Garnet (YIG) qualities as a resonator while allowing for wafer-scale implementation. Processes described herein also provide for fabrication of a plurality of resonators, including, for example, hundreds of resonators in parallel. Processes, device structures and systems described herein may apply to radio-frequency (RF) electronics, including but not limited to wafer-level implementation of YIG resonators using single-crystal spheres.

According to embodiments, one or more fabrication steps are provided to fabricate or form a stacked wafer including glass-blown nests for a ferrimagnetic sphere element. The glass nests are fabricated using wafer-level glassblowing fabrication technology. Processes are also provided for allowing a ferrimagnetic sphere, such as a YIG sphere, to be assembled with the wafer stacks. According to embodiments, a YIG sphere may be clamped from both ends by mutually orthogonal coupling loop coils, forming a tight “nest” for each YIG sphere. According to embodiments, process steps are also provided for forming coupling loop coils defined on an inner hemisphere and separated from YIG sphere for maximum RF-coupling efficiency. Tuning coils may be defined on the outer hemisphere and are used to create a uniform magnetic field for tuning the resonance frequency. This fabrication and assembly process enables production of potentially hundreds of YIG resonators in parallel decreasing product cost and lead time. Although processes herein are described for fabrication of YIG spherical resonators, however it should be appreciated that the principles described herein may apply to other materials.

According to embodiments, processes and device structures allow for reductions in manufacturing time and costs by providing a complete wafer-level process capable of fabricating/assembling hundreds of YIG resonators in parallel. Embodiments also provide fabrication processes that simplify integrating multiple resonators with small form factor, this is commonly used to construct bandpass/reject filters. In addition, glass blown hemispheres with loop-coupling coils permit extremely small coupling loops tightly coupled to the YIG sphere. The small size of the coupling loops minimizes the coupling-loop inductances in order to minimize self-resonances around the center frequency.

Aspects of the disclosure are also directed to a resonator structure that may be formed from one or more processes described herein. According to embodiments, a resonator structure may include first and second wafer-level glass blown wafer stacks. Each stack may include an inner hemisphere and an outer hemisphere, the inner hemisphere of each stack forming a nest for a ferrimagnetic element, such as a YIG sphere. Each wafer-level glass blown wafer stack may also include a coupling loop coil on an inner hemisphere and a tuning coil on an outer hemisphere. Embodiments are also provided for systems to perform processes described herein and for a resonator as described herein.

As used herein, the terms “a” or “an” shall mean one or more than one. The term “plurality” shall mean two or more than two. The term “another” is defined as a second or more. The terms “including” and/or “having” are open ended (e.g., comprising). The term “or” as used herein is to be interpreted as inclusive or meaning any one or any combination. Therefore, “A, B or C” means “any of the following: A; B; C; A and B; A and C; B and C; A, B and C”. An exception to this definition will occur only when a combination of elements, functions, steps or acts are in some way inherently mutually exclusive.

Reference throughout this document to “one embodiment,” “certain embodiments,” “an embodiment,” or similar term means that a particular feature, structure, or characteristic described in connection with the embodiment is included in at least one embodiment. Thus, the appearances of such phrases in various places throughout this specification are not necessarily all referring to the same embodiment. Furthermore, the particular features, structures, or characteristics may be combined in any suitable manner on one or more embodiments without limitation.

### Exemplary Embodiments

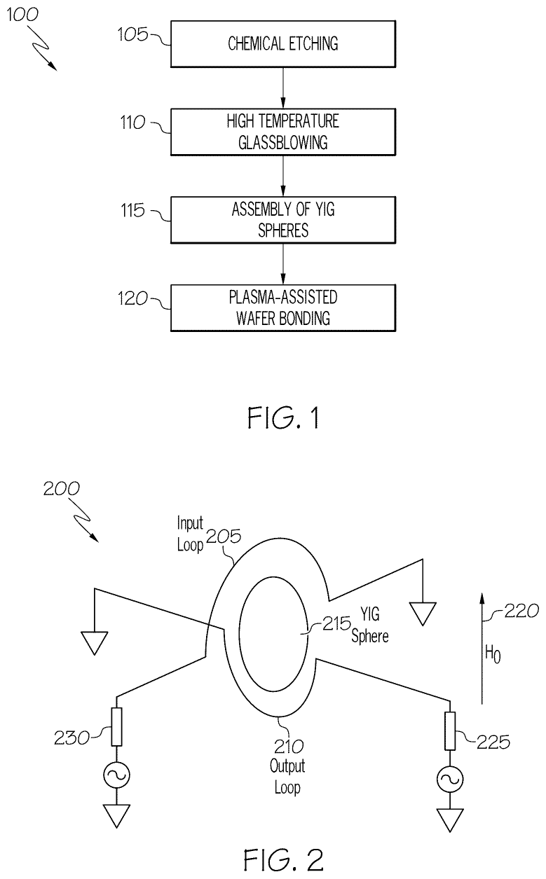

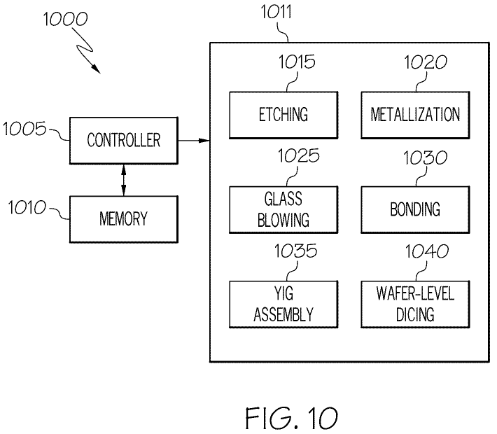

FIG. 1 illustrates process 100 for fabrication of at least one resonator according to one or more embodiments. According to embodiments, process 100 may be a manufacturing process for fabrication of a plurality of ferrimagnetic resonators, such as YIG resonators. Process 100 may be performed by a system, such as the system described herein with reference to FIG. 10, for the purpose of generating one or more wafer-level resonators. Embodiments described herein may generate resonators used for one or more of inertial sensing, mass sensing, time referencing, biosensing, etc.

Embodiments described herein may be wafer-level processes, such as process 100, for fabricating hundreds of resonators in parallel. Process 100 includes performing chemical etching at block 105 and high temperature glassblowing at block 110. Chemical etching at block 105 may be performed to etch cavities in a glass wafer and to etch one or more holes or patterns for elements of a resonator, such as coils and electrode pads. Accordingly, a wafer may be etched at block 105 and the wafer maybe processed with one or more additional steps, such as metallization prior to glassblowing at block 110. Wafer etching at block 105 may include etching of a cap wafer and of an inner wafer. Glassblowing at block 110 may be a high-temperature operation to form a hemisphere structure, such as a dual hemisphere structure, in a wafer stack from the one or more cavities. High temperature glassblowing at block 110 may modify shape and curvature of etched cavities. Following glass blowing of wafers at block 110, one or more operations, such as removal of a wafer handle may be performed, such that the wafer stacks may be used as an upper or lower portion of a resonator structure. According to embodiments, two wafer stacks are used to encapsulate a sphere element.

Process 100 also includes assembly of YIG spheres at block 115 and plasma-assisted wafer bonding at block 120. At block 115, ferrimagnetic spheres, such as a YIG sphere may be provided to a wafer stack. According to embodiments, self-assembly of a YIG sphere is provided such that the YIG sphere may be nested within a glass blown cavity. Wafer bonding at block 120 allows for ferrimagnetic spheres to be encapsulated. Unlike conventional processes that allow for fabrication of a single resonator, process 100 and embodiments described herein allow for fabrication of a plurality of resonators and for wafer-level fabrication to be performed. As a result, process 100 and embodiments described herein improve manufacturing, allow for greater frequency range and further improved manufacturing ability.

FIG. 2 illustrates a graphical representation of a YIG resonator 200 according to one or more embodiments. YIG resonator 200 includes an input loop 205, output loop 210, and YIG sphere 215. According to embodiments, a ferrimagnetic element, such as YIG sphere 215 is nested between structure generated by a wafer-level process, such that YIG sphere 215 resonates at a frequency when driven by output (e.g., magnetic field) of input loop 205. Output loop 210 outputs current from the magnetic field of the YIG sphere 215. According to embodiments, input loop 205 and output loop 210 may be two mutually orthogonal coupling loops placed in close proximity to YIG sphere 205. The resonant frequency of YIG sphere 215 may be directly proportional to a biasing magnetic field (H₀) 220 by the electromagnetic ratio. YIG sphere 215 may have a static magnetic field, and may be aligned according to its magnetic field with respect to input loop 205 and output loop 210. According to embodiments, micro-scale coupling loop coils and RF-spherical coils may be employed by YIG resonator 200 defined by a wafer-level glass blowing technique. According to embodiments, YIG resonator 200 includes an outer and inner hemispherical structure. The inner hemisphere of the structure may include RF coils to drive and detect resonance in YIG sphere 215. Accordingly, input loop 205 may include RF loop 230 to drive resonance and output loop 210 may RF loop 225 to detect resonance.

Ferrimagnetism is the magnetic property of materials having atomic moments aligned in opposite directions. According to embodiments, YIG is a ferrite material with excellent magnetic and magneto-electric properties that make it the best magnetic material for high frequency applications, spanning from 500 MHz to 50 GHz. Due to its high electrical resistivity, high radiation stability, comparatively low magnetization, and narrow ferrimagnetic linewidth and thus low loss, YIG suits many microwave, and potentially mm-wave applications such as circulators, isolators, and phase shifting devices. YIG oscillators are suitable in high-end equipment. The ultra-high Q-factor, tunability, and very long service life of YIG oscillators are attractive, praised for high signal quality, ultra-low phase jitter, and broadband characteristics (with a very linear tuning curve).

YIGs are most often used in a sphere configuration. Other shapes have also been investigated over the years, in particular thin films, however the case of the sphere is of special interest in the design of YIG filters because only in this shape of resonator is the resonant frequency directly proportional to the direct magnetic field. The normal modes of a spherical YIG resonator are circularly polarized and distribution of internal fields remarkably takes the form of the free space. This makes the YIG resonator in the form of a sphere the most desirable. It is attractive to reduce the size of YIG spheres because it permits a uniform magnetic field in the volume of a sphere (critical for reduction of the peak broadening).

According to embodiments, the alignment of YIG spheres along the desired axis can be tuned to minimize temperature dependence of the resonant frequency or minimize the biasing magnetic field needed for high frequency resonance. It is known that YIG has a cubic magneto-crystalline anisotropy, with an “easy” axis along the [111] direction. This can be exploited for alignment, as applying strong magnetic field pulses will induce a torque on the sphere, causing the nearest [111] axis to align along the external magnetic field. Embodiments can provide for alignment without the use of a thermally conducting rod.

Embodiments preserve all exceptional qualities of the YIG crystal as ferrimagnetic resonator and provide a process for wafer-scale implementation. The YIG sphere 215 will be clamped from both ends by mutually orthogonal coupling loop coils, shown as inner loop 205 and outer loop 210, forming a tight “nest” for YIG sphere 215. According to embodiments, glass nests are fabricated using wafer-level glassblowing fabrication technology to support the loop coils. According to embodiments, coupling loop coils are defined on an inner hemisphere and separated from YIG sphere by ˜5 μm of glass for maximum RF-coupling efficiency. According to embodiments, tuning coils are defined on an outer hemisphere and are used to create a uniform magnetic field for tuning the resonance frequency. This fabrication and assembly process enables production of potentially hundreds of YIG resonators in parallel decreasing product cost and lead time.

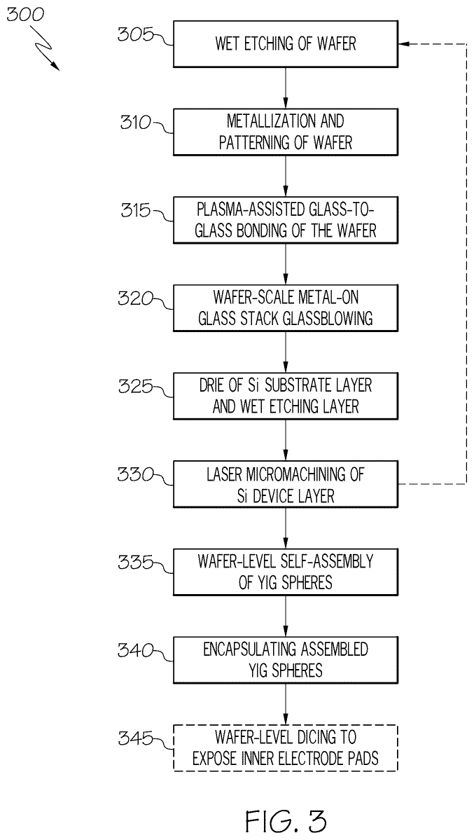

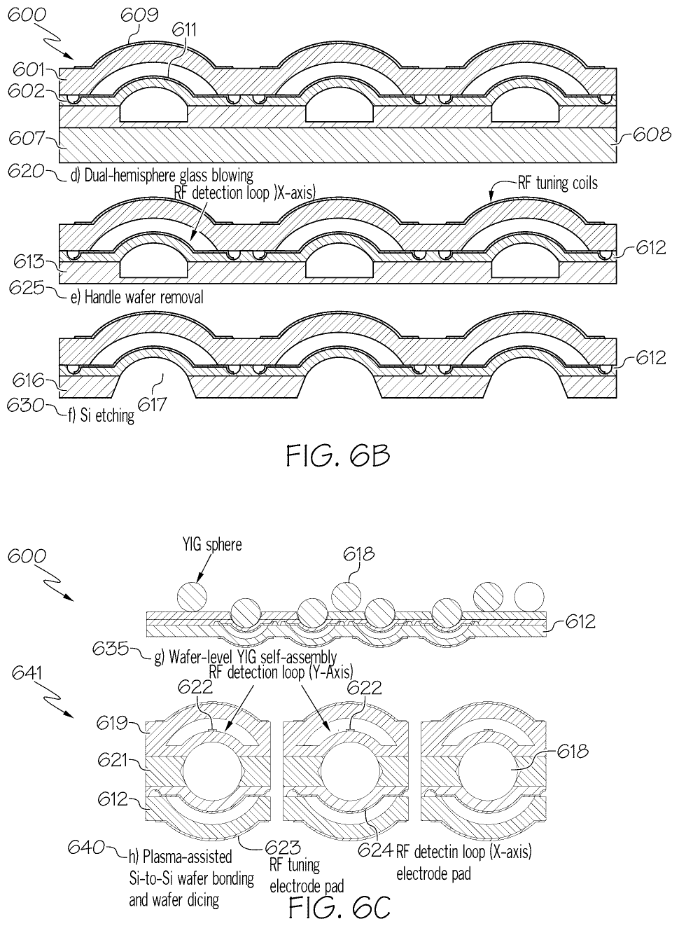

FIG. 3 illustrates a process for fabrication of at least one resonator according to one or more embodiments. Process 300 provides a wafer-level fabrication process including fabrication steps to fabricate or form a stacked wafer including glass-blown nests for a ferrimagnetic sphere element. According to embodiments, one or more wafer stacks may be generated to form upper and lower stacks to encapsulate a YIG sphere. FIG. 6 illustrates a graphical representation of process 300 according to embodiments. According to embodiments, process 300 may be controlled by one or more devices or controllers, such as a processor, for controlling manufacturing.

Process 300 includes wet etching a wafer at block 305 to generate or form cavities. Process 300 may include controlling isotropic cavity etching of at least one glass wafer, such as a cap wafer and an inner wafer. The cap wafer and an inner wafer may be glass wafers and processes for glass blowing may relate to shaping and/or modifying the structure of the cap wafer and inner wafer. At block 310, metallization and patterning may be performed on the cap wafer and inner wafer to define coils for coupling and tuning. At least one of a top coil and bottom coil are formed. At block 315, plasma assisted glass-to-glass wafer bonding may be performed to bond the cap wafer to the inner wafer. Bonding at block 315 may include anodic-boding of the assembled inner and cap wafers to a silicon on insulator (SOI) wafer.

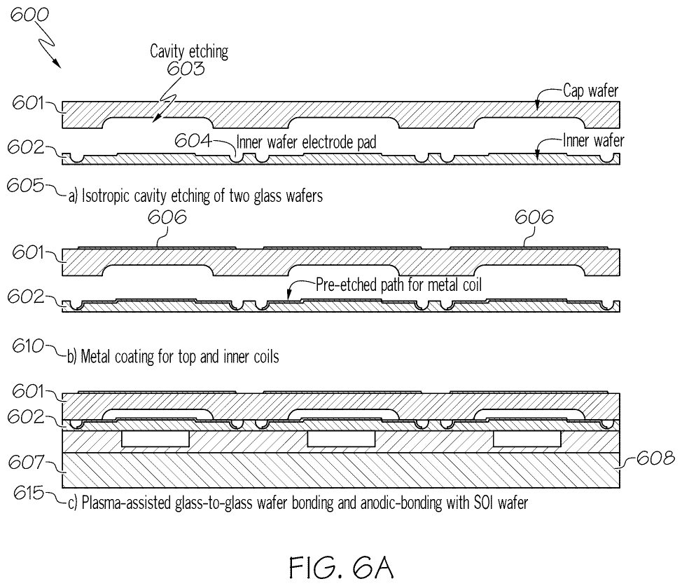

At block 320, glass blowing of the bonded wafer may be controlled to form a dual hemisphere structure. The hemispherical structure may include three-dimensional coils and loops formed from metallization and shaping of the etched cavities. FIG. 5 illustrates an graphical representation of coils according to embodiments. At block 325, deep reactive-ion etching (DRIE) may be performed for removal of a handle wafer from the bonded wafer. At block 330, laser micromachining of a silicon (Si) device layer may be controlled to form at least one nest for a sphere element. Process 300, following block 330, provides a structure to receive a YIG sphere. According to embodiments, the structure generated by process 300 through block 330 may be a first bonded wafer to provide a portion for encapsulation of the YIG sphere. According to embodiments, the structure following block 330 may provide a plurality of nests forming one half of a structure to receive a YIG sphere. Accordingly, in embodiments, process 300 may optionally include repeating blocks 305 to 330 to form an additional bonded wafer to encapsulate YIG spheres in addition to the first bonded wafer.

At block 335, wafer-level self-assembly of YIG Spheres may be performed. According to embodiments, assembly of a sphere element with the bonded wafer can allow for one or more YIG spheres to be positioned relative to the bonded wafer nests. Once YIG spheres are nested in a bonded wafer, the YIG spheres may be encapsulated at block 340 by bonding an additional, or second wafer. Block 340 may include controlling wafer-to-wafer bonding of the bonded wafer to form a resonator. Process 300 may optionally include wafer-level dicing to form resonator dies optional block 345.

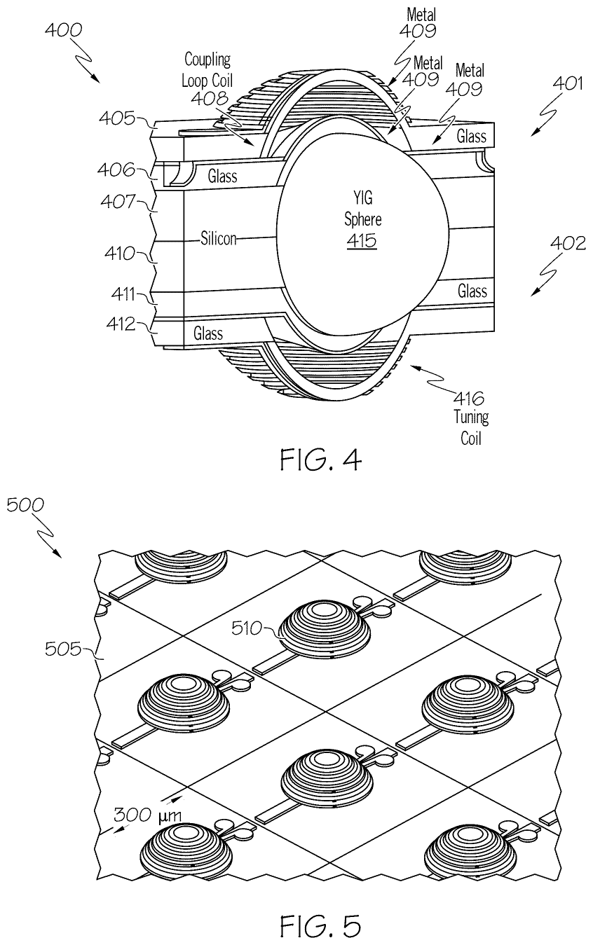

FIG. 4 illustrates a graphical representation of YIG resonator 400 according to one or more embodiments. Resonator 400 may be formed from one or more processes described herein. According to embodiments, resonator 400 includes an encapsulated ferrimagnetic sphere within a first wafer stack 401 and second wafer stack 402. According to embodiments, first wafer stack 401 and second wafer stack 402 are each wafer-level glass blown wafer stacks including an inner hemisphere and an outer hemisphere. First wafer stack 401 includes glass layer 405 including an outer hemisphere and glass layer 406 including an inner hemisphere. Glass layer 405 is bonded to glass layer 406, and glass layer 406 is bonded to silicon layer 406. According to embodiments glass layers 405 and 406 include metal patterns 409. As shown in FIG. 4, first wafer stack 401 is a top stack encapsulating YIG sphere 415.

Second wafer stack 402 includes glass layer 412 including an outer hemisphere and glass layer 411 including an inner hemisphere. Glass layer 412 is bonded to glass layer 412, and glass layer 412 is bonded to silicon layer 410. According to embodiments glass layers 411 and 412 include metal patterns. Glass layer 411 includes coupling loop coil on an inner hemisphere and a tuning coil 416 on an outer hemisphere.

According to embodiments, outer and an inner hemispherical structures of resonator 400 are co-fabricated simultaneously. The inner hemisphere is used to define RF loops to drive and detect resonance in YIG spheres; the process allows placement of RF loops just a few microns away from YIG spheres, thus optimizing coupling efficiency. The outer hemisphere is used to define harmonic magnetic coils, and the hemispherical shape provides the maximum uniformity for tuning the magnetic field and therefore, the frequency of the resonator.

According to embodiments, first wafer stack 401 and second wafer stack 402 provide glass nests fabricated using wafer-level glassblowing fabrication technology. Processes are also provided for allowing a ferrimagnetic sphere, such as a YIG sphere 415, to be assembled with the wafer stacks. According to embodiments, YIG sphere 415 may be clamped from both ends by mutually orthogonal coupling loop coils, forming a tight “nest” for each YIG sphere. According to embodiments, process steps are also provided for forming coupling loop coils defined on an inner hemisphere and separated from YIG sphere by ˜5 μm of glass for maximum RF-coupling efficiency. Tuning coils, such as tuning coil 416, may be defined on the outer hemisphere and are used to create a uniform magnetic field for tuning the resonance frequency. The fabrication and assembly processes described herein enable production of potentially hundreds of YIG resonators in parallel decreasing product cost and lead time. Although processes herein are described for fabrication of YIG spherical resonators, however it should be appreciated that the principles described herein could apply to other ferrimagnetic materials.

FIG. 5 illustrates a graphical representation of a YIG resonator elements according to one or more embodiments. According to embodiments, a plurality of hemispherical structures 500 may be formed on a wafer stack 505. Wafer stack 505 includes tuning coils, such as tuning coil 550. According to embodiments, glass blowing is performed to control hemispherical shape. The hemispherical shape and metallization of a glass layer may be used to define harmonic magnetic coils, such as tuning coil 510 formed on outer hemisphere. FIG. 5 illustrates several hemispherical structures 500 on a single wafer stack 505. According to embodiments, cach of the tuning coils, including tuning coil 510, are raised above wafer stack 505.

FIGS. 6A-6C graphically illustrate a process for fabrication of a resonator according to one or more embodiments. According to embodiments, process 600 provides a graphical representation of operations associated with process 300 of FIG. 3. Process 600 provides a wafer-level fabrication process. According to embodiments, process 600 may be controlled by one or more devices or controllers, such as a processor, for controlling manufacturing. FIGS. 6A-6B illustrate processes including fabrication steps to fabricate or form a stacked wafer including glass-blown nests for a ferrimagnetic sphere element. FIG. 6C illustrates self-assembly of a ferrimagnetic (e.g., YIG) sphere and wafer-to-wafer bonding to encapsulate the sphere.

According to embodiments, process 600 includes isotropic cavity etching of two glass wafers shown as 605. At 605, process 600 includes wet etching a wafer to generate or form cavities 603. Process 600 may include isotropic cavity etching of at least one glass wafer, including cap wafer 601 and inner wafer 602. Cap wafer 601 and inner wafer 602 may be glass wafers and processes for glass blowing may relate to shaping and/or modifying the structure of the one or more glass wafers. Inner wafer 602 may be etched for inner electrode wafer pads 604. At 605, etching may be performed to generate cavities 603 which will define air pockets for glassblowing. According to embodiments, 10% hydrofluoric acid (HF) is used for wet etching of cavities 603. Cap wafer 601 and inner wafer 602 may be made of pyrex wafer having 100 μm thickness. According to embodiments, holes for inner RF coil traces and electrode pads on the inner side of inner wafer 602, with inner wafer 602 on the order of 50 μm.

At 610, process 600 includes metallization and patterning on cap wafer 601 and inner wafer 602 to define coils for coupling and tuning. At least one of a top coil and bottom coil are formed shown as 606. According to embodiments, e-beam metallization and patterning of a metal stack (0.4 μm/0.6 μm/0.5 μm Au/Cu/Cr) on both cap wafer 601 and inner wafer 602 as top RF coils and inner RF detection coils. At 615, plasma assisted glass-to-glass wafer bonding may be performed to bond the cap wafer 601 to inner wafer 602. Bonding at 615 may include anodic-boding of the assembled inner and cap wafers to a silicon on insulator (SOI) wafer 607 to form bonded wafer 608. According to embodiments, bonding at 615 includes aligning wafers and anodic bonding of the glass stack to a silicon on insulator handle wafer with pre-etched cavities. Bonding at 615 may also allow for assembly of a wafer stack prior to glassblowing.

FIG. 6B continues process 600 at 620 with glass blowing of bonded wafer 608 to form dual hemisphere structures. Glass blowing at 620 may include wafer-scale metal-on-glass stack glassblowing at high temperature (c.g., 850° C.). The hemispherical structure 609 may include three-dimensional coils and loops formed from metallization and shaping of the etched cavities. Dual hemispheres are formed from the cap wafer hemisphere 609 and inner wafer hemisphere 611. Glass blowing may form three-dimensional coils 609 and loops 611 from metallization patterned to portions of the inner and cap wafer.

At 625, deep reactive-ion etching (DRIE) may be performed for removal of a handle wafer 613 from bonded wafer 612. DRIE may be performed on a silicon substrate layer and wet etching of than oxide layer on the SOI handle to open the handle wafer. At 630, laser micromachining of a silicon (Si) device layer 616 may be controlled to form at least one nest 617 for a sphere element. Multiple nests are included in bonded wafer 612. According to embodiments, bonded wafer after micromachining at 630 provides a structure to receive a YIG sphere. Femtosecond (f-s) laser micromachining may be performed at 630 of a Si device laser on SOI wafer to form nests with about 100 μm diameter, these nests may be YIG nests.

According to embodiments, bonded wafer 612 may be a first bonded wafer to provide a portion for encapsulation of the YIG sphere. Bonded wafer 612 as shown at 630 may provide a plurality of nests forming one half of a structure to receive a YIG sphere. According to embodiments, process 600 may optionally include repeating operations to form an additional bonded wafer to encapsulate YIG spheres in addition to the first bonded wafer. Repeating the operations may be performed to generate one or more wafer stacks to form upper and lower stacks to encapsulate a YIG sphere.

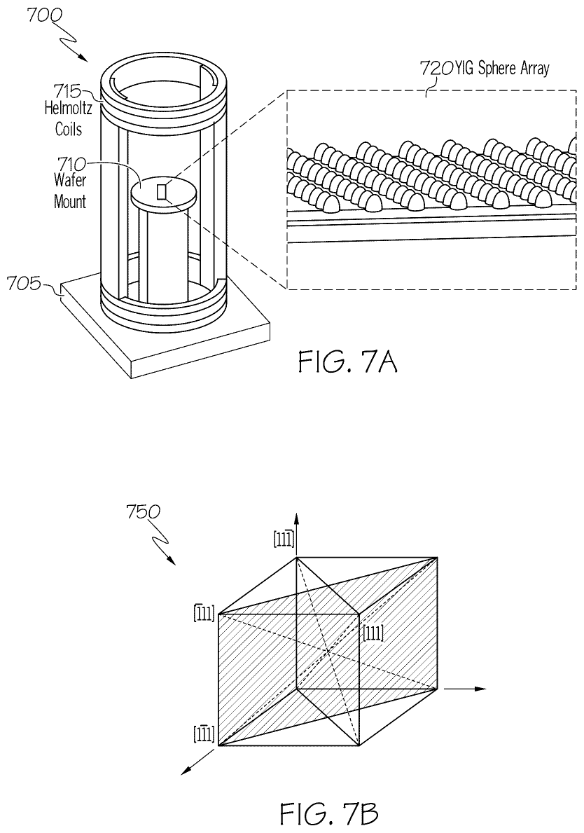

FIG. 6C continues process 600 at 635 with wafer-level self-assembly of YIG spheres. According to embodiments, assembly of a sphere element with the bonded wafer can allow for one or more YIG spheres to be positioned relative to the bonded wafer nests. According to embodiments, self-assembly of YIG spheres may include using a surface treatment and mechanical vibration. Self-assembly may also include use of a fixture, such as fixture 700 of FIG. 7A to align spheres along a crystal axis. As used herein, self-assembly of YIG spheres may include one or more operations for positioning a YIG sphere, such as YIG sphere 618 within a nest of bonded wafer 612.

Once YIG spheres are nested in a bonded wafer 612, the YIG spheres may be encapsulated at 640 by bonding an additional, or second wafer. At 640, wafer-to-wafer bonding may be controlled of the bonded wafer to form a resonator. Wafer-wafer bonding at 640 may be performed by plasma assisted Si-to-Si wafer-level bonding to a symmetric wafer stack, such as bonded wafer 619. Bonded silicon Si layers are shown as 621. Each resonator 641 at 640 includes an RF detection loop 622 (y-axis), RF tuning electrode pad 623, and RF detection loop (x-axis) 624. Process 600 may optionally include wafer-level dicing to form resonator dies, as shown in FIG. 6C with separated resonator unites. Wafer-level dicing may be performed to expose inner electrode pads of RF (e.g., RF tuning electrode pad 623) and detection coils (e.g., RF detection loop 622, 624).

FIGS. 7A-7BC illustrate alignment according to one or more embodiments. According to embodiments, one or more fixtures and operations may be performed for assembly of ferrimagnetic spheres, such as YIG spheres, within a wafer nests. Embodiments provide a process for alignment assembly with a wafer.

FIG. 7A illustrates alignment setup 700 including fixture 705. Fixture 705 may include wafer mount 710 and Helmholtz coils 715. According to embodiments, fixture 705 may allow for minimizing overall resonator size. According to embodiments, another goal may be to align one or more YIG spheres to the “easy” axis (e.g., [111] direction) perpendicular to the wafer stack. As a result, the biasing magnetic field necessary for high frequency resonance will be minimized. Due to size constraints, it is impossible to attach a rod to the sphere as is done in hand-assembled YIG resonators. According to embodiments, spheres may be held in place via ultraviolet light (UVL) cured epoxy. As a result, sphere alignment cannot be tuned after the epoxy is applied and accurate alignment on the wafer level is critical.

According to embodiments, alignment processes may be simplified from existing methods. Rather than aligning to the (110) plane (typical for rod-mounted spheres) or the temperature insensitive axis (<225>direction), embodiments may align any [111] direction perpendicular to the wafer stack. FIG. 7B illustrates a direction plane 750 as an example. Any [111] direction (e.g., [111], [1 1̅1], [11 1̅], and [111 ]̅) of any polished YIG sphere with high sphericity will align along the pulsed magnetic field regardless of initial orientation. Therefore, only one Helmholtz coil aligned perpendicular to the wafer stack is needed rather than multiple coils precisely aligned relative to one another. According to embodiments, a proposed alignment process is wafer-level and depending on the die and wafer size could be performed on hundreds of YIG spheres at once. Fixture 705 is an exemplary custom alignment setup to facilitate wafer mount 710, Helmholtz coils 715, and a microscope to inspect the movement of the spheres when pulses are applied, epoxy dispenser for tacking spheres, and UV light for curing the epoxy. FIG. 7A provides a representation of alignment setup for a YIG sphere array 720 and [111] cubic crystal directions. FIG. 7A and embodiments described herein may provide for assembly of YIG spheres including self-assembly. According to embodiments, an alignment process by alignment setup 700 can include sourcing a wafer stack with YIG spheres self-assembled via vibration. The wafer stack may then be placed with YIG spheres on wafer mount 710 to prepare for alignment. According to embodiments, Helmholtz coils 715 may be controlled to generate magnetic field perpendicular to wafer stack. According to another embodiment, the wafer stack may be pulsed (e.g., ˜100 times) to achieve the desired alignment of the YIG spheres in the array of YIG nests. Pulsing may be performed for alignment with a [111] axis perpendicular to wafer stack. Epoxy may be applied in cavities and cured using ultraviolet light. Epoxy may serve to hold YIG spheres as aligned. The assembly may also include verifying correct alignment using x-ray techniques. Verification of alignment may also be used to verify yield.

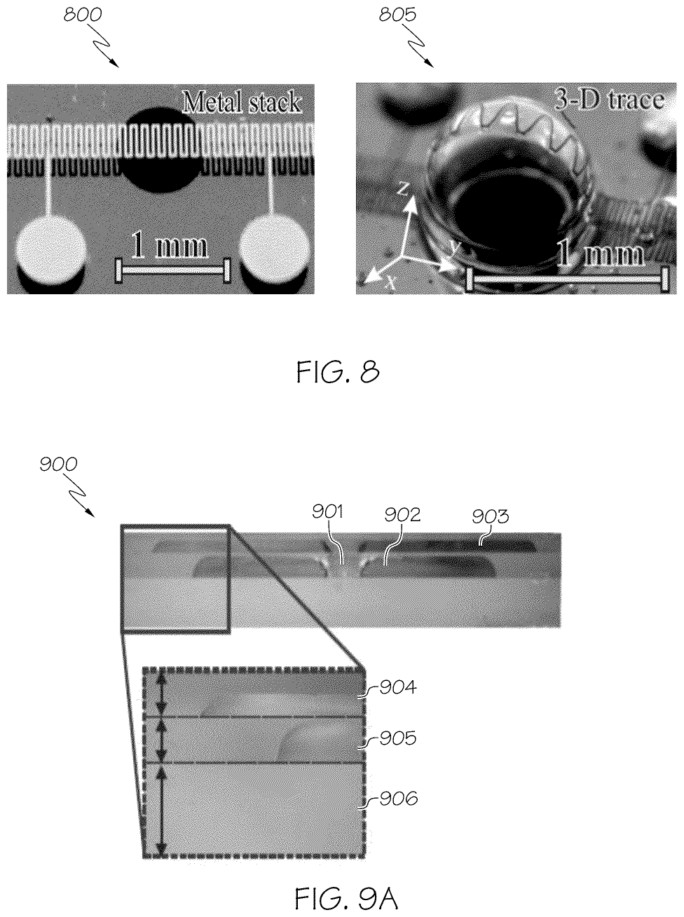

FIG. 8 illustrates a tuning coil according to one or more embodiments. According to embodiments, a tuning coil design is provided for resonators. Tuning coil structure and design as described herein may be configured to maximize the homogeneity of the generated field within the smallest form factor. The deformation of the coil during the glassblowing can be modeled using stereographic projection to design the layout of the metal mask. The feasibility of the of blowing a glass+metal stack has been demonstrated and is shown in FIG. 8 for experimental results. By way of example, a stack of Au, Cu, and Cr was used to define the metal layer on a glass wafer. FIG. 8 illustrates an Au/Cu/Cr metal stack 800 on a 2D surface before high temperature glass blowing. When placed in a furnace the metal stack was ductile enough to successfully deform with the glass layer during the glassblowing process, demonstrating the feasibility of the coupling loop and tuning coil design. A 2D pattern transferred to a 3D surface is shown as 805 which survived glassblowing.

Experimental results are described for dual-hemisphere glassblowing (c.g., glassblowing at block 320, at 620). According to embodiments, process flow of the dual-hemispherical structure starts with two high-purity fused quartz (FQ) wafers coated with 2 μm undoped polysilicon layers on both sides as the masking material. After patterning the polysilicon hard mask, the cavities of the two FQ wafers were pre-etched in the isotropic wet etching process to achieve the desired depth using hydrofluoric (HF) acid (49 wt. % in water solution). The polysilicon hard mask was removed afterward, and then the two FQ were aligned and bonded to a blank FQ substrate wafer using plasma-assisted direct bonding. The triple-stacked FQ wafer was annealed after bonding to complete the bond formation. An array of aligned cavities were formed after the three-wafer stack was completed.

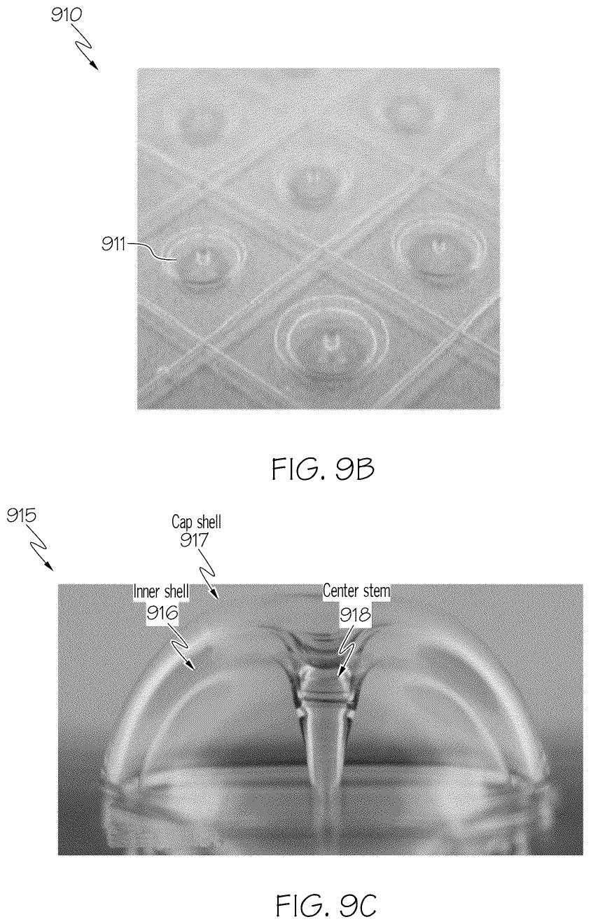

FIG. 9A illustrates a double cavity structure 900 according to one or more embodiments. Double cavity structure 900 is shown in a cross-sectional view and includes a triple-stack of fused quartz dies prior to glassblowing. Double cavity structure 900 includes central stem 901, device cavity 902 and cap cavity 903. The triple-stack is provided by cap wafer 904, device wafer 905 and substrate wafer 906 shown in enlarged view. A glassblowing process was performed in a Rapid Thermal Processing (RTP) furnace at 1550° C. The glassblowing temperature was chosen above the softening point of the fused quartz when the viscosity drops, and fused quartz becomes a viscous fluid. The triple-stacked FQ wafer was placed in a uniform temperature zone of the furnace, and then the glassblowing was performed. FIG. 9B illustrates a bonded wafer stack 910 including concentric cavities 911.

FIG. 9C illustrates a dual hemisphere shell 915 according to one or more embodiments. Dual hemisphere shell 915 includes inner shell 916, cap shell 917 and center stem 918. As shown in FIG. 9C, center stem 918 is included connecting the inner and outer hemispheres. According to embodiments, dual hemisphere may be provided without center stem 918.

FIG. 10 illustrates a system for fabrication of a resonator according to one or more embodiments. According to embodiments, system 1000 includes controller 1105 and memory 1010. Controller 1005 may be coupled to one or more fabrication units 1101 and configured to control fabrication units to form a resonator. According to embodiments, system 1000 may include a plurality of controllers including a controller for each of the fabrication units 1011.

According to embodiments, system 1000 may include memory 1010. Controller 1005 may relate to a processor or control device configured to execute one or more operations stored in memory 1010. System 1000 may perform one or more operations including process 300 of FIG. 3 and process 600 of FIG. 6 for control of fabrication units 1011 by controller 1005.

According to embodiments, fabrication units 1011 may include one or more devices or assemblies for fabrication of a resonator including a ferrimagnetic element as described herein. Controller 1005 may be configured to control operations of one or more of an etching unit 1015, metallization unit 1020, glass blowing 1025, bonding unit 1030, YIG assembly unit 1035 and wafer level dicing 1040.

While this disclosure has been particularly shown and described with references to exemplary embodiments thereof, it will be understood by those skilled in the art that various changes in form and details may be made therein without departing from the scope of the claimed embodiments.

1. A method for wafer-level fabrication of a resonator, the method comprising:
controlling, by a device, isotropic cavity etching of at least one glass wafer, including a cap wafer and an inner wafer;
controlling, by the device, metallization of the cap wafer and inner wafer, wherein at least one of a top coil and bottom coil are formed;
controlling, by the device, wafer bonding of the at least one glass wafer with a silicon wafer to form a bonded wafer;
controlling, by the device, glass blowing of the bonded wafer to form a dual hemisphere structure;
controlling, by the device, removal of a handle wafer from the bonded wafer;
controlling, by the device, etching of the bonded wafer to form at least one nest for a sphere element;
controlling, by the device, assembly of a sphere element with the bonded wafer; and
controlling, by the device, wafer-to-wafer bonding of the bonded wafer to form a resonator.

2. The method of claim 1, wherein isotropic cavity etching includes wet etching at least one cavity in the cap wafer and at least one hole for a coil trace and at least on electrode pad in the inner wafer.

3. The method of claim 1, wherein controlling metallization of the at least one glass wafer includes metallization and patterning of a metal stack on the cap wafer and the inner wafer.

4. The method of claim 1, wherein wafer bonding of the at least one glass wafer with a silicon wafer includes plasma-assisted glass-to-glass bonding of the cap wafer and the inner wafer to form a glass stack, aligning of the glass stack, and bonding of the glass stack to a handle wafer.

5. The method of claim 1, wherein controlling glass blowing includes wafer-scale metal-on-glass stack glassblowing.

6. The method of claim 1, wherein controlling removal of a handle wafer of the bonded wafer includes etching of a silicon substrate layer and wet etching of an oxide layer on the handle wafer.

7. The method of claim 1, wherein controlling etching of the bonded wafer to form at least one nest includes laser micromachining of a silicon device layer.

8. The method of claim 1, wherein controlling assembly includes control of yttrium iron garnet (YIG) spheres with the bonded wafer and includes self-assembly of at least one YIG sphere using surface treatment and mechanical vibration.

9. The method of claim 1, wherein controlling wafer-to-wafer bonding to form a resonator includes encapsulating an yttrium iron garnet (YIG) sphere by plasma assisted silicon-to-silicon wafer-level bonding.

10. The method of claim 1, further comprising controlling, by the device, wafer-level dicing to expose at least one inner electrode pad of a detection coil.

11. A system for wafer-level fabrication of a resonator, the system comprising:
a controller, etching unit, metallization unit, glass blowing unit, bonding unit, and YIG assembly unit, wherein the controller is configured to
control isotropic cavity etching of at least one glass wafer, including a cap wafer and an inner wafer;
control metallization of the cap wafer and inner wafer, wherein at least one of a top coil and bottom coil are formed;
control wafer bonding of the at least one glass wafer with a silicon wafer to form a bonded wafer;
control glass blowing of the bonded wafer to form a dual hemisphere structure;
control removal of a handle wafer from the bonded wafer;
control etching of the bonded wafer to form at least one nest for a sphere element;
control assembly of a sphere element with the bonded wafer; and
control wafer-to-wafer bonding of the bonded wafer to form a resonator.

12. The system of claim 11, wherein isotropic cavity etching includes wet etching at least one cavity in the cap wafer and at least one hole for a coil trace and at least on electrode pad in the inner wafer.

13. The system of claim 11, wherein controlling metallization of the at least one glass wafer includes metallization and patterning of a metal stack on the cap wafer and the inner wafer.

14. The system of claim 11, wherein wafer bonding of the at least one glass wafer with a silicon wafer includes plasma-assisted glass-to-glass bonding of the cap wafer and the inner wafer to form a glass stack, aligning of the glass stack, and bonding of the glass stack to a handle wafer.

15. The system of claim 11, wherein controlling glass blowing includes wafer-scale metal-on-glass stack glassblowing.

16. The system of claim 11, wherein controlling removal of a handle wafer of the bonded wafer includes etching of a silicon substrate layer and wet etching of an oxide layer on the handle wafer.

17. The system of claim 11, wherein controlling etching of the bonded wafer to form at least one nest includes laser micromachining of a silicon device layer.

18. The system of claim 11, wherein controlling assembly includes control of yttrium iron garnet (YIG) spheres with the bonded wafer and includes self-assembly of at least one YIG sphere using surface treatment and mechanical vibration.

19. The system of claim 11, wherein controlling wafer-to-wafer bonding to form a resonator includes encapsulating an yttrium iron garnet (YIG) sphere by plasma assisted silicon-to-silicon wafer-level bonding.

20. A resonator comprising:
a first wafer-level glass blown wafer stack including an inner hemisphere and an outer hemisphere;
a second wafer-level glass blown wafer stack including an inner hemisphere and an outer hemisphere, wherein each wafer-level glass blown wafer stack includes a coupling loop coil on an inner hemisphere and a tuning coil on an outer hemisphere;
and
a sphere element nested between the first wafer-level glass blown wafer stack and the second wafer-level glass blown wafer stack.
